(19) United States
(12) Patent Application Publication
(10) Pub. No.: US 2026/0349062 A1
(43) Pub. Date: Nov. 5, 2026

(54) METHOD AND APPARATUS FOR MEASURING SIGNAL DELAY OF CHIP TESTER, AND COMPUTER DEVICE

(71) Applicant: SUZHOU HYC TECHNOLOGY CO., LTD., Suzhou (CN)

(72) Inventors: Tong YIN, Suzhou (CN); Yaming DONG, Suzhou (CN); Xiaobin JIN, Suzhou (CN)

(21) Appl. No.: 19/115,533

(22) PCT Filed: Aug. 29, 2023
(86) PCT No.: PCT/CN2023/115507

§ 371 Date: Mar. 26, 2025

(30) Foreign Application Priority Data
Oct. 9, 2022 (CN) 202211225564.6

(51) Int. Cl. G01R 35/00; G01R 31/317

(52) U.S. Cl. CPC G01R 35/00; G01R 31/31725

(57) ABSTRACT

Method and apparatus for measuring signal delay of a chip tester, and a computer device are provided. The method includes: performing a vector signal test on a target channel, the vector signal test utilizing a test vector signal, with a timing phase point, generated by the chip tester; upon completion of the vector signal test, moving a position of the timing phase point and re-performing a vector signal test on the target channel; repeating processes of moving the position of the timing phase point and re-performing the vector signal test on the target channel, until a number of vector signal tests reaches a preset standard; and when the number of vector signal tests reaches the preset standard, obtaining level comparison results of the number, and performing a delay calculation based on the level comparison results of the number to obtain signal delay time.

### CROSS-REFERENCE TO RELATED APPLICATION

The present disclosure is a U.S. National Stage Application, filed under 35 U.S.C. 371, of International Patent Application No. PCT/CN 2023/115507, filed on Aug. 29, 2023, which claims priority to Chinese patent application No. 202211225564.6, titled “METHOD AND APPARATUS FOR MEASURING SIGNAL DELAY OF CHIP TESTER, AND COMPUTER DEVICE”, filed on Oct. 9, 2022, the entire content of which is incorporated herein by reference.

### TECHNICAL FIELD

The present disclosure relates to the field of chip testing, and in particular, to a method for measuring signal delay of a chip tester, an apparatus therefor and a computer device.

### BACKGROUND

With the development of chip technology, how to conduct chip test efficiently and accurately becomes more and more important. Typically, automatic test equipment (ATE) may be used for performing tests on the chips. The ATE is a chip tester used in the semiconductor industry. A master control chip of the ATE can generate a stimulus timing output in a specific format according to a preset script program and send the generated stimulus timing output to a chip under test. The chip under test is usually placed on a test board (also referred to as business board) of the ATE, and is connected to the master control chip of the ATE through a connector, a load board and multiple lines. The load board is a mechanical and circuital interface board that can connect the tester and devices under test. The stimulus timing output from the ATE is typically transmitted in a form of pattern (vector signal), so chip test is generally called pattern test.

However, the ATE generally tests multiple chips under test simultaneously when performing chip testing. These chips under test may be located on the same test board or on different test boards. Even if they are located on the same test board, due to different connection lines at various positions on the test board, there may exist a length deviation between actual signal transmission paths of signal channels established between respective chips under test and the master control chip of the ATE. If they are located on different test boards, the deviation turns more significant. Path length deviations between respective channels cause different time of arrival of signals sent from the master control chip of the ATE to the chips under test, resulting in a decrease in the pattern time margin. In some high-speed application scenarios, different time of arrival or the signals or different time of reading of the signals can further cause timing logic errors, thereby adversely affecting the entire pattern test, resulting in errors and causing great interference to chip testing.

Consequently, it is necessary to provide a method which can determine signal delay time caused by path length deviations between the channels.

### SUMMARY

According to embodiments of the present disclosure, a method for measuring signal delay of a chip tester, an apparatus therefor, and a computer device are provided.

In a first aspect, a method for measuring signal delay of a chip tester is provided according to an embodiment of the present disclosure. The method includes:
performing a vector signal test on a target channel, the vector signal test utilizing a test vector signal, with a timing phase point, generated by the chip tester;
here, performing the vector signal test on the target channel includes: sending the test vector signal to the target channel; obtaining a reflected vector signal of the test vector signal; and comparing a level at the timing phase point in the reflected vector signal with a preset comparison level, and recording a level comparison result;
moving a position of the timing phase point in the test vector signal upon completion of the vector signal test, and re-performing a vector signal test on the target channel;
repeating processes of moving the position of the timing phase point and re-performing the vector signal test on the target channel until a number of vector signal tests reaches a preset standard; and
when the number of the vector signal tests reaches the preset standard, obtaining level comparison results of the number, and performing a delay calculation based on the level comparison results of the number to obtain signal delay time.

In an embodiment, after recording the level comparison result, the method further includes:
performing a binary processing on the level comparison result to obtain data to be processed; and
performing data accumulation on the data to be processed, a result of the data accumulation being applied to the delay calculation which is performed after the number of the vector signal tests reaches the preset standard to obtain the signal delay time.

In an embodiment, performing the binary processing on the level comparison result to obtain the data to be processed includes:
comparing the level of the timing phase point with the preset comparison level, and obtaining the data to be processed based on a comparison result.

In an embodiment, before performing the vector signal test on the target channel, the method further includes:
determining a measurement mode, where each measurement mode has a corresponding number of vector signal tests; and
determining the preset standard for the number of the vector signal tests according to the measurement mode.

In an embodiment, the measurement mode includes one or more selected from a group consisting of a performance mode, a balance mode, and a fast mode;
a number of tests for the performance mode, a number of tests for the balance mode, and a number of tests for the fast mode decrease sequentially;
a test accuracy of the performance mode, a test accuracy of the balance mode, and a test accuracy of the fast mode decrease sequentially; and
a moving interval of the timing phase point for the performance mode, a moving interval of the timing phase point for the balance mode, and a moving interval of the timing phase point for the fast mode increase sequentially.

In an embodiment, moving the position of the timing phase point includes:
obtaining a current test order;
calculating a displacement distance according to the current test order and a preset point moving step; and
moving the timing phase point by the displacement distance to a target position.

In an embodiment, after obtaining the signal delay time, the method further includes:
generating time compensation data according to the signal delay time, the time compensation data being utilized by the chip tester to implement signal timing compensation.

In an embodiment, after obtaining the signal delay time, the method further includes:
changing a length of the target channel;
performing signal delay measurement on the target channel with the changed length to obtain a displacement signal delay time; and
generating displacement difference time compensation data according to a difference between the signal delay time and the displacement signal delay time.

In an embodiment, moving the position of the timing phase point includes:
setting a comparison point step, the comparison point step being a fixed length of time; and
moving the timing phase point by a distance equal to the comparison point step within a cycle.

In an embodiment, performing the delay calculation based on the level comparison results of the number to obtain the signal delay time includes:
finding, from the level comparison results of the number, a timing phase point at which the level of the timing phase point is higher than the preset comparison level to obtain a target timing phase point;
obtaining a basic time according to a serial number of a cycle in which the target timing phase point is located;
calculating an additional time according to an initial position of the target timing phase point, the number, and a magnitude of the comparison point step; and
adding the basic time and the additional time to obtain the signal delay time.

In an embodiment, the test vector signal is pre-set with the timing phase point in each cycle, and positions of the timing phase points in respective cycles are the same.

In an embodiment, sending the test vector signal to the target channel includes:
setting an end of the target channel to be an open circuit state, and sending the test vector signal with the timing phase point to the target channel, the target channel being a line channel through which a signal is sent to a location for placing a chip under test.

In a second aspect, the present disclosure further provides an apparatus for measuring signal delay of a chip tester. The apparatus includes:
a test module, configured to perform a vector signal test on a target channel, the vector signal test utilizing a test vector signal, with a timing phase point, generated by the chip tester, performing the vector signal test on the target channel including: sending the test vector signal to the target channel; obtaining a reflected vector signal of the test vector signal; and comparing a level at the timing phase point in the reflected vector signal with a preset comparison level, and recording a level comparison result;
a timing module, configured to move a position of the timing phase point;
a master control module, configured to control the timing module to repeatedly move the position of the timing phase point and further configured to control the test module to re-perform a vector signal test on the target channel until a number of vector signal tests reaches a preset standard; and
a data processing module, configured to obtain level comparison results of the number when the number of the vector signal tests reaches the preset standard, and perform a delay calculation based on the level comparison results of the number to obtain signal delay time.

In a third aspect, the present disclosure further provides a computer device, including a memory and a processor. The memory stores a computer program thereon. The processor, when executing the computer program, performs steps of any one of the above methods.

In a fourth aspect, the present disclosure further provides a chip tester, including a memory and a processor. The memory stores a computer program thereon. The processor, when executing the computer program, performs steps of any one of the above methods.

One or more embodiments of the present disclosure will be described in detail below with reference to drawings. Other features, objects and advantages of the present disclosure will become more apparent from the description, drawings, and claims.

### BRIEF DESCRIPTION OF THE DRAWINGS

In order to describe the technical solutions of the embodiments of the present disclosure or the conventional art more clearly, the accompanying drawings required for describing the embodiments or for describing the conventional art will be briefly introduced as follows. Apparently, the accompanying drawings, in the following description, illustrate merely some embodiments of the present disclosure, for a person of ordinary skill in the art, other drawings can also be obtained according to these accompanying drawings without making any creative efforts.

FIG. 1 is a flowchart of a method for measuring signal delay of a chip tester in an embodiment;

FIG. 2 is a flowchart of performing a vector signal test on a target channel in an embodiment;

FIG. 3 is a flowchart of steps after step S206 shown in FIG. 2 in an embodiment;

FIG. 4 is a flowchart of determining a measurement mode in an embodiment;

FIG. 5 is a flowchart of moving a position of a timing phase point in an embodiment;

FIG. 6 is a schematic diagram showing an accumulation result obtained by performing data accumulation on data to be processed in an embodiment;

FIG. 7 is a flowchart of performing delay compensation for a line channel with a changed length in an embodiment;

FIG. 8 is a schematic diagram showing a configuration of an apparatus for measuring signal delay of a chip tester in an embodiment;

FIG. 9 is a schematic diagram showing a configuration of a system for measuring compensation for signal delay of a chip tester in an embodiment;

FIG. 10 is a flowchart of a method for measuring compensation for signal delay of a chip tester in an embodiment;

FIG. 11 is a flowchart of a method for implementing timing compensation in an embodiment; and

FIG. 12 is a schematic diagram showing an internal configuration of a computer device in an embodiment.

The components in the accompanying drawings are marked as follows: 70—host computer, 80—programmable logic device center, 602—test module, 604—timing module, 606—master control module, 608—data processing module, 702—master control measurement module, 704—pattern control module, 706—data reading and parsing module, 708—data accumulation and processing module, 710—file generation module, 802—pattern data storage module, 804—output module, 806—receiving and comparing module, 808—comparison data reader-writer, 7041—timing control unit, 7042—level control unit, 8021—timing parameter storage unit, 8022—level parameter storage unit.

### DETAILED DESCRIPTION OF THE EMBODIMENTS

The technical solutions of the embodiments of the present disclosure will be described clearly and completely below with reference to the accompanying drawings of the embodiments of the present disclosure. Apparently, the described embodiments are a part of but not all of the embodiments of the present disclosure. Based on the embodiments in the present disclosure, all other embodiments obtained without any creative efforts by a person of ordinary skill in the art fall within the scope of protection of the present disclosure.

It should be noted that the terms “first”, “second”, etc. in the description and claims of the present disclosure and the above drawings are used to distinguish similar objects, rather than to describe a specific order or sequence. It is to be understood that the terms so used are interchangeable under an appropriate circumstance such that the embodiments of the present disclosure described herein may be operate in sequences other than those illustrated or described herein. The implementations described in the following exemplary embodiments do not represent all implementations consistent with the present disclosure. Rather, they are merely examples of apparatuses and methods consistent with some aspects of the present disclosure as recited in the appended claims. The terms “include”, “comprise”, or any other variation thereof are intended to cover non-exclusive inclusion such that a process, a method, a product, or an apparatus, including a series of elements, includes not only these elements, but also other elements not expressly listed, or also includes elements inherent to such process, method, product, or apparatus. Without further limitation, it does not exclude the existence of additional identical or equivalent elements in the process, method, product or apparatus including one element. For example, if the terms “first”, “second”, etc. are used, they are used to indicate names of elements and do not indicate any particular order.

It should be noted that terms “couple”, “connect”, etc. described in the present disclosure may indicate direct connections through interfaces or pins between devices, connections through leads, or wireless connections (communication connections).

Generally, when an automatic test equipment (ATE), which can also be referred to as “chip tester”), performs chip testing on chips under test (also be referred to as devices under test, DUTs), there is a length deviation between different lines, resulting in different time of arrival of a pattern at the chips under test. To address this problem, delay time can be obtained by providing an external device to sequentially measure respective line channels. However, such approach is time-consuming and labor-intensive since the ATE has a large number of test channels. It is required to provide additional device according to a model of the ATE. In addition, the delay time measurement procedure may be subjected to problems such as difficulty in finding measurement points, a limited number of channels for single measurement, and complex data recording and calculations that are prone to errors. As a result, the delay time measurement may be time-consuming, and may be of low precision and large errors.

To address the above problems, as shown in FIG. 1, a method for measuring signal delay of a chip tester is provided. The method includes the following steps.

In step S20, a vector signal test is performed on a target channel. The vector signal test utilizes a test vector signal, with a timing phase point, generated by the chip tester.

The target channel is a signal transmission channel between a master control chip of the ATE and a chip under test. The vector signal test can be achieved through a pattern test function of the ATE. Using a pattern test of the ATE, a pattern (vector signal) can be sent to the target channel, and a timing phase point can be set. The pattern can be detected at a measurement end of the ATE, and a level at the timing phase point can be compared with a preset value. The timing phase point may be a point pre-set on a time axis of the pattern. The timing phase point may refer to a symbol representing a certain time point in a system in a timing diagram. Timing phase points can be used to identify events or state variations that occur at respective time points in the system. The timing phase points may be denoted as vertical lines or arrows, and can be utilized in cooperation with information in the timing diagram to describe interactions and timing relationships between respective participants in the system.

Specifically, the ATE activates the pattern test function and sends the test vector signal to the target channel according to a preset instruction. A reflected vector signal is acquired by the ATE to obtain a pattern test result. The test vector signal includes a specific timing phase point and a level. The pattern test result may be a level comparison result obtained by the ATE through its own comparison function.

It should be noted that, this solution needs to measure time of arrival of a signal from the master control chip of the ATE to the chip under test on a business board. It is possible that no chip is placed at a location for placing a chip under test on the business board during the pattern test. In this case, an end of a channel from the master control chip of the ATE to the location for placing the chip on the business board can be designed as open-circuited.

In step S30, upon completion of the vector signal test, a position of the timing phase point is moved, and a vector signal test is re-performed on the target channel.

Specifically, the position of the timing phase point is changed, and a test vector signal with the changed timing phase point is sent to the target channel to obtain a pattern test result. In some implementations, a comparison point step may be set. The comparison point step is a fixed length of time. The timing phase point is moved by a distance equal to the comparison point step within a cycle. For example, the comparison point step may be set to be 20 picoseconds (ps), and accordingly, the timing phase point may be moved forward by 20 ps along the time axis.

In step S40, processes of moving the position of the timing phase point and re-performing the vector signal test on the target channel are repeated until a number of vector signal tests reaches a preset standard.

The number of the vector signal tests may be a number of pattern tests that the master control chip of the ATE has performed on the target channel. The preset standard may be a number of pattern tests that the master control chip of the ATE needs to perform according to the preset instruction.

Specifically, the position of the timing phase point is moved multiple times, and one pattern test is performed on the target channel after each movement until a preset number of tests is reached.

Step S50, when the number of the vector signal tests reaches the preset standard, level comparison results of the number are obtained, and a delay calculation is performed based on the level comparison results of the number to obtain signal delay time.

The level comparison results of the number may be level comparison results obtained after performing the vector signal tests. For example, if 10 times of vector signal tests are performed, the level comparison results of the number may be results of 10 times of level comparisons.

Specifically, after completing the preset number of pattern tests, the results of the multiple pattern tests may be subjected to a comprehensive calculation to obtain the signal delay time. For example, the reflected vector signals of the multiple pattern tests can be combined onto a same time axis, and the signal delay time can be calculated based on the level comparison results of the timing phase points. In some implementations, a timing phase point at which the level of the timing phase point is higher than a preset comparison level can be found from the level comparison results of the number, and a basic time can be obtained according to a serial number of a cycle in which the timing phase point is located. Then, an additional time is obtained through a comprehensive calculation according to an initial position of the timing phase point, the number of the vector signal tests, and a magnitude of the comparison point step. The signal delay time can be obtained by adding the basic time and the additional time.

In the technical solution provided by the embodiments of the present disclosure, the vector signal test is performed on the target channel through the pattern test function of the ATE. Furthermore, the timing phase point is set on the vector signal, by moving the timing phase point multiple times and performing multiple tests, the signal delay time is calculated according to the test results. In this way, the signal delay time across a large number of channels can be measured using ATE's own function without the assistance of any external device, thereby saving time and cost spent on measurement. In addition, the calculation can be performed after changing the timing phase point multiple times, and thus the obtained signal delay time is of smaller error and the result is more accurate.

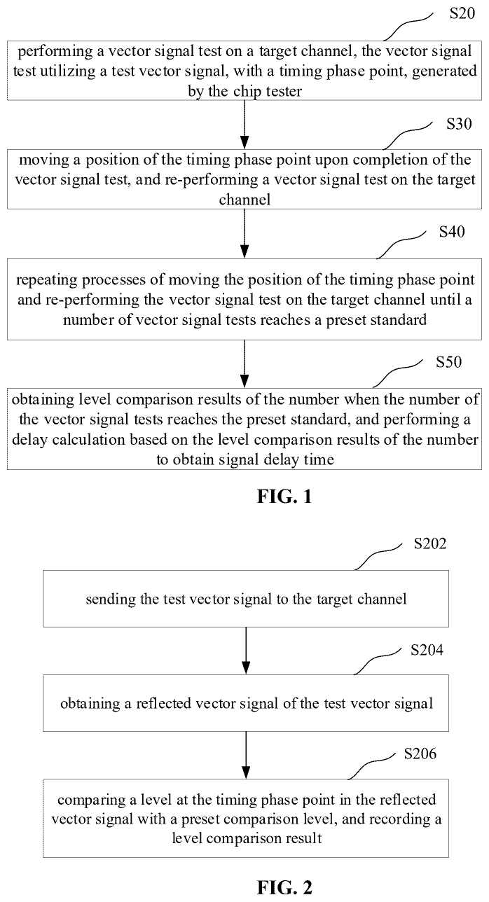

In an embodiment, as shown in FIG. 2, performing the vector signal test on the target channel includes the following steps.

In step S202, the test vector signal is sent to the target channel.

The test vector signal may be a vector signal generated by a pattern test module of the ATE. The vector signal is typically a signal with a magnitude and a direction, and the direction of the vector indicates the phase or relative position of the signal. A cycle of the test vector signal may be set to be Per. Per is a time unit for vector signal output and comparison. The specific value of Per may be customized and the unit is seconds. In some implementations, former N cycles output a low level, and latter N cycles output a high level, for a total of 2N cycles, where N is a positive integer. The timing phase point is preset in each cycle of the test vector signal, and positions of the timing phase points in respective cycles are the same.

Specifically, an end of the target channel is set to be an open circuit state, and the master control chip of the ATE sends the test vector signal with the timing phase point to the target channel. The target channel is a line channel through which the ATE sends a signal to a location for placing the chip under test. The end of the target channel may be an end of a connection line between the ATE and the chip under test, and the end refers to an end at the side of the chip under test. It should be understood that when the end of the target channel is set to be the open circuit state, no chip is placed at the end of the connection line. The open circuit state generally refers to a state in which the circuit is interrupted or disconnected. In the open circuit state, a current cannot pass through the end of the target channel, and devices or components after the end of the target channel cannot operate normally.

In step S204, a reflected vector signal of the test vector signal is obtained.

Specifically, the ATE may receive the reflected vector signal returned from the target channel.

According to the reflection principle of time domain signals, a pulse or step signal is sent to the transmission path; when the impedance changes in the transmission path, a part of the energy is reflected and the remaining energy continues to be transmitted. Since the end of the target channel is set to be open-circuited in the step S202, it is equivalent that an infinite resistance is externally connected to the end of the target channel, and the signal sent returns along the original path after reaching the end of the target channel. Since the returned reflected vector signal may meet a part of the sent test vector signal, a region where the test vector signal and the reflected vector signal are superimposed and mixed can be detected at the measurement end of the ATE. For example, in a case that the test vector signal is set to have a low level of L and a high level of H, a signal amplitude M in the superposition region of the high level and the low level can be detected at the measurement end, where M is equal to (H−L)/2+L. Further, the low level of the test vector signal may be set to be 0, and then the reflected vector signal can be calculated at the measurement end according to the detected signal amplitude of the superposition region of the high level and the low level.

In step S206, a level at the timing phase point in the reflected vector signal is compared with a preset comparison level, and a level comparison result is recorded.

If the amplitude of the signal superposition region is set to be M, and the preset comparison level is set to be X, then M is less than X, and X is less than H, where M is equal to (H−L)/2+L, H is the high level of the test vector signal, and L is the low level of test vector signal. Optionally, X is equal to 0.75×(H−L)+L. Further, L may be 0, in this case, X is equal to 0.75H.

It should be understood that the reflected vector signal has the same maximum level as the test vector signal.

Specifically, the level at the timing phase point can be compared with the preset comparison level through the comparison function of the ATE, and the level comparison result can be written into a designated memory.

In the above embodiment, the test vector signal with the preset phase point is sent to the channel through the ATE, and the level at the phase point in the reflected vector signal is compared with the preset comparison level by using the comparison function of the ATE, and the comparison result is recorded. In this way, without the assistance of any external device, the pattern test of the target channel can be achieved through the ATE's own functional module, and the level comparison result can be recorded, thereby simplifying the test procedure and improving the test efficiency.

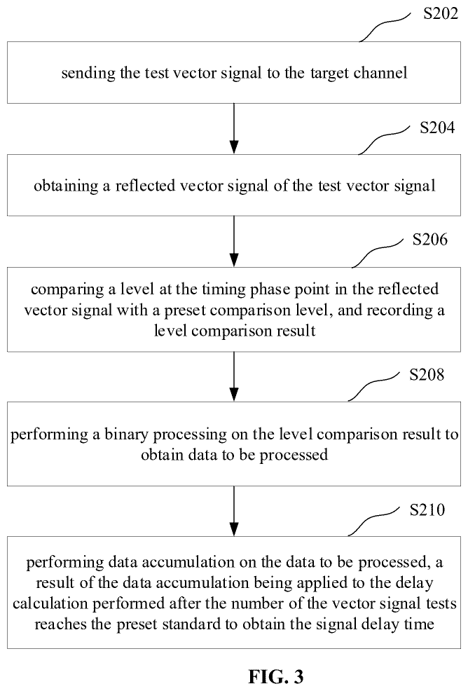

In an embodiment, as shown in FIG. 3, after recording the level comparison result, the method further includes the following steps.

In step S208, a binary processing is performed on the level comparison result to obtain data to be processed.

Specifically, the level at the timing phase point is compared with the preset comparison level. In a case that the level of the timing phase point is lower than the preset comparison level, the level comparison result can be recorded as 0, and in a case that the level of the timing phase point is higher than the preset comparison level, the level comparison result can be recorded as 1. The recorded 0 or 1 is determined as the data to be processed.

In step S210, data accumulation is performed on the data to be processed. A result of the data accumulation is applied to the delay calculation which is performed after the number of the vector signal tests reaches the preset standard to obtain the signal delay time.

Specifically, the data to be processed obtained from the level comparison result of each pattern test may be subjected to an accumulation processing, and a current number of pattern tests can be recorded. When the number of pattern tests reaches the preset number, the accumulated data is subjected to calculation to obtain the signal delay time.

In the above embodiment, the level comparison result of the timing phase point is converted into the form of 0 or 1, which facilitates the storage, accumulation and reading of data, thereby improving the data processing efficiency and reducing the overall time spent on measurement.

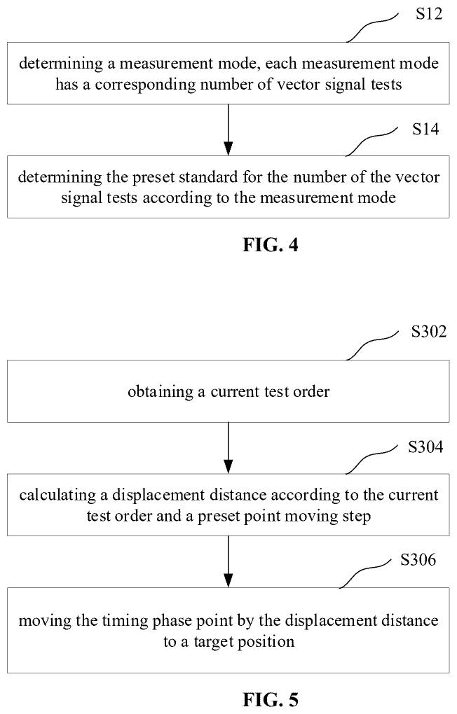

In an embodiment, as shown in FIG. 4, before performing the vector signal test on the target channel, the method further includes the following steps.

In step S12, a measurement mode is determined. Each measurement mode has a corresponding number of vector signal tests.

The measurement mode may be a signal delay measurement mode preset by the ATE according to different times of vector signal tests performed on the channel. For example, depending on different measurement requirements, one or more measurement modes such as a performance mode, a balance mode, and a fast mode may be provided. In the three measurement modes, the performance mode has a largest number of tests, a smallest moving interval of the timing phase point, and a highest test accuracy. The balance mode has a medium number of tests, a medium moving interval of the timing phase point, and a moderate test accuracy and moderate test time. The fast mode has a least number of tests, a largest moving interval of the timing phase point, and shortest test time. In other words, the number of tests for the performance mode, the number of tests for the balance mode, and the number of tests for the fast mode decrease sequentially; the test accuracy of the performance mode, the test accuracy of the balance mode, and the test accuracy of the fast mode decrease sequentially; and the moving interval of the timing phase point for the performance mode, the moving interval of the timing phase point for the balance mode, and the moving interval of the timing phase point for the fast mode increase sequentially.

In step S14, a preset standard for the number of vector signal tests is determined according to the measurement mode.

Specifically, different measurement modes generally result in different numbers of tests, so the preset standard for the number of vector signal tests can be determined according to different measurement modes.

In the above embodiment, according to different measurement requirements for the signal delay of the chip tester, a measurement mode adapted to an actual requirement can be determined, thereby avoiding mechanical and fixed measurement procedure and measuring the signal delay time much more efficiently.

In an embodiment, as shown in FIG. 5, moving the position of the timing phase point includes the following steps.

In step S302, a current test order is obtained.

The current test order is an order of a current vector signal test to be performed in vector signal tests that need to be performed by the ATE during a current signal delay measurement procedure. It should be understood that the method for measuring signal delay provided in the embodiment of the present disclosure includes multiple times of performing the vector signal test on the target channel. For example, the preset number of vector signal tests during the signal delay measurement is 10 times, then the current test order is 2 after a first vector signal test is performed, and the current test order is 5 after a fourth vector signal test is performed.

In step S304, a displacement distance is calculated according to the current test order and a preset point moving step.

The point moving step may be a fixed length of time.

Specifically, the current test order is multiplied by the preset point moving step to obtain the displacement distance. For example, if the current test order is 2 and the point moving step is 20 picoseconds (ps), the displacement distance is 40 ps.

In step S306, the timing phase point is moved by the displacement distance to a target position.

Specifically, the timing phase point may be moved forward by the displacement distance. For example, when the displacement distance is 40 ps, the timing phase point is moved forward by 40 ps along the time axis. In some other implementations, the timing phase point may be moved backward by the displacement distance.

In the above embodiment, a rule for movement of the timing phase point can be defined according to the test order and the set point moving step, rather than based on manual definition and calculation, the rule can be reused. In this way, repeated determinations about the movement of the timing phase point due to different test times can be avoided. In addition, according to the predefined rule for movement, a time difference between a final position of the timing phase point and an initial position of the timing phase point in the first vector signal test can be obtained according to test results, so as to further determine the signal time delay.

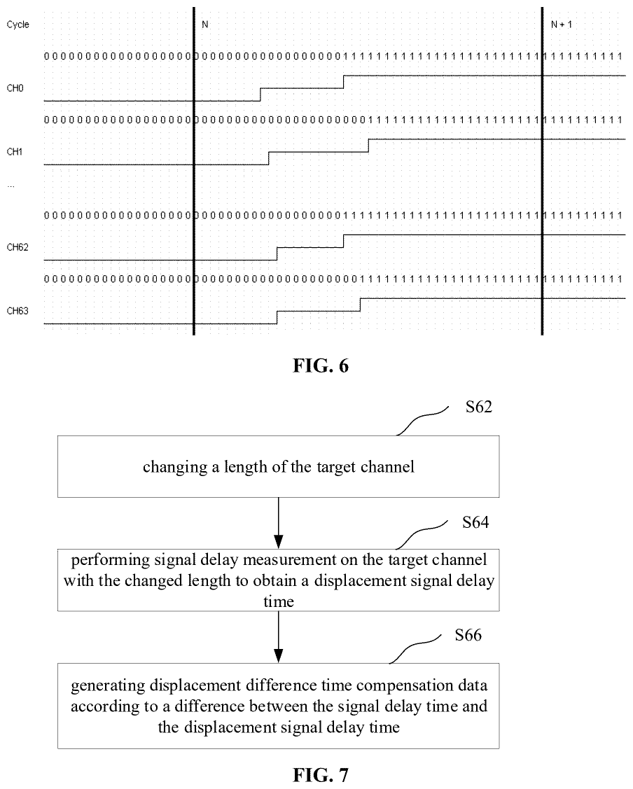

FIG. 6 is a schematic diagram showing an accumulation result of data accumulation for data to be processed in an embodiment. As shown in FIG. 6, Cycle represents cycles, which is utilized to calculate a row number of an edge. CH0, CH1, CH62, and CH63 represent serial numbers of target channels. Target channels with serial numbers from CH2 to CH61 between target channels with serial numbers of CH1 and CH62 are not shown in FIG. 6. N and N+1 represent serial numbers of cycles.

According to the manner of moving the timing phase point as described in steps S304 to S306 and the accumulated data obtained from converting the level comparison results of the timing phase points as described in steps S208 to S210, performing the delay calculation based on the results of the vector signal tests in step S50 may include:

determining a row number of an edge and a weighted position of the edge from the accumulated data for the target channel, and calculating the signal delay time according to the row number and the weighted position.

The edge refers to a jumping position where the level of the timing phase point is higher than the preset comparison level. For example, in FIG. 6, a position where the number representing the level comparison result jumps from 0 to 1 corresponds to a vector signal jumping position, i.e., the edge. The row number refers to a number of complete cycles preceding the edge. For example, the edge in FIG. 6 is located at an N-th cycle, and there are N−1 complete cycles preceding this edge, so the row number is N−1. The weighted position may include an initial weighted position and a step position. The initial weighted position is an initial position of the timing phase point in the cycle. The step position is a distance that the timing phase point moves according to the comparison point step, and the step position can be obtained according to the comparison point step and the number of tests.

Specifically, the row number is multiplied by cycle length (the basic time can be obtained through the multiplication), and the product of the multiplication is added with the weighted position (the additional time) to obtain the signal delay time.

In an embodiment, after obtaining the signal delay time, the method further includes:
generating time compensation data according to the signal delay time, where the time compensation data is utilized by the chip tester to implement signal timing compensation.

Specifically, after the signal delay time is obtained, the time compensation data may be generated according to actual needs. For example, if the signal delay time obtained in the step S50 is 5 nanoseconds (ns), 5 ns can be taken as the time compensation data.

In some other implementations, a compensation file or a compensation program may be further generated according to the time compensation data. The compensation file or compensation program can be written into a storage module of the chip tester or into an external memory. The compensation file or compensation program, when executed by the chip tester, implement timing compensation for the signal of the chip tester, to enable the time when the signal arrives at the end of the channel to meet actual requirements.

In the above embodiment, the time compensation data can be generated according to the signal delay time, and the compensation file or the like can be further generated, which facilitate the chip tester in achieve timing compensation and timing synchronization of signals. In this way, the time when the test signals or the vector signals sent by the chip tester arrive at ends of channels can meet requirements for chip testing.

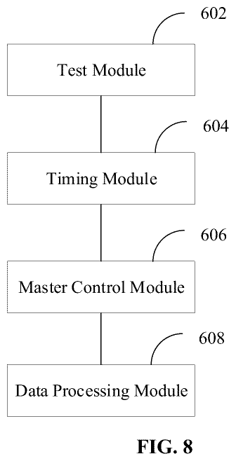

In an embodiment, as shown in FIG. 7, after obtaining the signal delay time, the method further includes the following steps.

In step S62, a length of the target channel is changed.

Specifically, the length of the target channel can be changed by increasing or decreasing a length of a line between the master control chip of the ATE and a connection port of the chip under test.

In step S64, signal delay measurement is performed on the target channel with the changed length to obtain a displacement signal delay time.

The displacement signal delay time is a delay time for the signal to arrive at the end of the target channel with the changed length.

Specifically, after the length of the target channel is changed, steps S20 to S50 are performed, and the displacement signal delay time is obtained through step S50. Alternatively, in some other implementations, steps S30 to S50 may be performed to obtain the displacement signal delay time. It should be understood that the procedure of signal delay measurement for the target channel with the changed length may be the same as or different from the measurement procedure before the change of the length.

In step S66, displacement difference time compensation data is generated according to a difference between the signal delay time and the displacement signal delay time.

According to the principle of time domain reflection, the increment in the time duration of the reflection superposition region is the same as the increment in line length at the end of the channel. Therefore, a difference between the signal delay time measured before the length of the target channel is changed and the displacement signal delay time measured after the length of the target channel is changed can be calculated. The obtained difference can represent variation of the signal delay time caused by the increase or decrease in the length of the target channel, and corresponding time compensation data can be generated based on the difference.

In the above embodiment, twice signal delay measurements are performed respectively before and after the length of the target channel is changed, and the time compensation data is generated according to the difference between the results obtained through the twice measurements. In this way, uncertainty about determining the signal delay time due to the change in the line length of the channel can be avoided.

It should be understood that although the individual steps in the flowcharts involved in the embodiments as described above are shown sequentially as indicated by arrows, the steps are not necessarily performed sequentially in the order indicated by the arrows. Unless explicitly stated herein, the execution of these steps is not strictly limited in any order and these steps can be performed in any other order. Moreover, at least some of the steps in the flowcharts involved in the embodiments as described above may include multiple sub-steps or multiple stages that are not necessarily performed simultaneously, but may be performed at different moments. The order in which these sub-steps or stages are performed is not necessarily sequential, and these sub-steps or stages may be performed in turn or alternately with at least some of other steps or at least some of sub-steps or stages in other steps.

In another aspect, an apparatus for measuring signal delay of a chip tester is further provided according to an embodiment of the present disclosure. As shown in FIG. 8, the apparatus includes:

a test module 602, which is configured to perform a vector signal test on a target channel, where the vector signal test utilizes a test vector signal, with a timing phase point, generated by the chip tester;

a timing module 604, which is configured to move a position of the timing phase point;

a master control module 606, which is configured to control the timing module to repeatedly move the position of the timing phase point and further configured to control the test module to re-perform a vector signal test on the target channel, until a number of vector signal tests reaches a preset standard; and a data processing module 608, which is configured to obtain level comparison results of the number when the number of the vector signal tests reaches the preset standard, and perform a delay calculation based on the level comparison results of the number to obtain signal delay time.

The specific limitations to the above-mentioned apparatus for measuring signal delay of the chip tester may be understood with reference to the limitations to the foregoing method for measuring signal delay of the chip tester, so these limitations are not repeated here. The individual modules in the above-mentioned apparatus for measuring signal delay of the chip tester can be implemented in whole or in part by software, hardware and a combination thereof. Each of the above modules may be embedded in or independent of a processor in a computer device in hardware form, or may be stored in software form on a memory in the computer device, so that the processor can call these modules to perform operations corresponding to these modules.

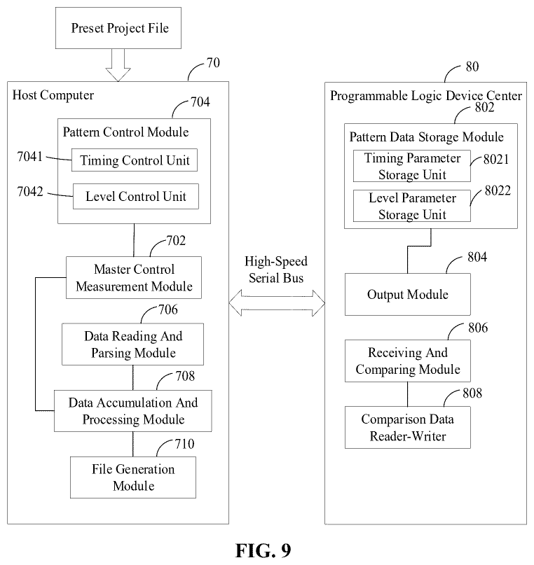

FIG. 9 is a schematic diagram showing a configuration of a system for measuring compensation for signal delay of a chip tester in an embodiment. The system includes a host computer 70 and a programmable logic device center 80. The host computer 70 and the programmable logic device center 80 can communicate via a high-speed serial bus. The programmable logic device center 80 may be an FPGA device. The host computer 70 may be an electronic device including a processor, such as a computer device, an industrial computer including a CPU or an MCU, an electronic device based on an embedded operating system, etc. The host computer 70 can also read external preset project files to obtain measurement information such as measurement-related instructions and parameters.

The host computer 70 includes the following modules.

A master control measurement module 702 is configured to set, according to a measurement mode, a preset number of vector signal tests to be performed on a target channel, and further configured to control an entire measurement procedure after the signal delay measurement starts until a number of vector signal tests performed on the target channel reaches the preset number and complete the measurement.

A pattern control module 704 is configured to control the issuing of pattern data and instructions, set a cycle and a timing phase point, and set a specification of an output level and an amplitude of a comparison level, etc. The pattern control module 704 includes a timing control unit 7041 and a level control unit 7042. The timing control unit 7041 is configured to set an initial position of the timing phase point in a pattern, and further configured to move the timing phase point. The level control unit 7042 is configured to control a level of a generated pattern.

A data reading and parsing module 706 is configured to read a level comparison result in a comparison data reader-writer 808 after each pattern test is performed, and further configured to perform binary conversion on the level comparison result to obtain data to be processed.

A data accumulation and processing module 708 is configured to accumulate and cache the data to be processed, and further configured to process the accumulated and cached data after all pattern tests are completed to obtain signal delay compensation data.

A file generation module 710 is configured to generate a delay compensation file according to the signal delay compensation data and store the delay compensation file into a memory of the chip tester.

The programmable logic device center 80 includes the following modules.

A pattern data storage module 802 is configured to store data related the pattern. The pattern data storage module 802 includes a timing parameter storage unit 8021 and a level parameter storage unit 8022. The timing parameter storage unit 8021 is configured to store the position of the timing phase point in the pattern. The level parameter storage unit 8022 is configured to store level parameters of the pattern.

An output module 804 is configured to output a test vector signal to the target channel according to the stored pattern data.

A receiving and comparing module 806 is configured to receive a reflected vector signal returned from the target channel, and compare a level at the timing phase point in the reflected vector signal with a preset comparison level to obtain a level comparison result.

The comparison data reader-writer 808 is configured to record the level comparison result. The programmable logic device center 80 can store the result into a double data rate (DDR) synchronous dynamic random-access memory through the comparison data reader-writer 808, and read back the comparison result within each cycle during a current pattern test after the pattern test is completed.

It should be understood that the system for measuring compensation for signal delay of the chip tester shown in FIG. 9 can be applied to an ATE chip tester having an operating environment for the system.

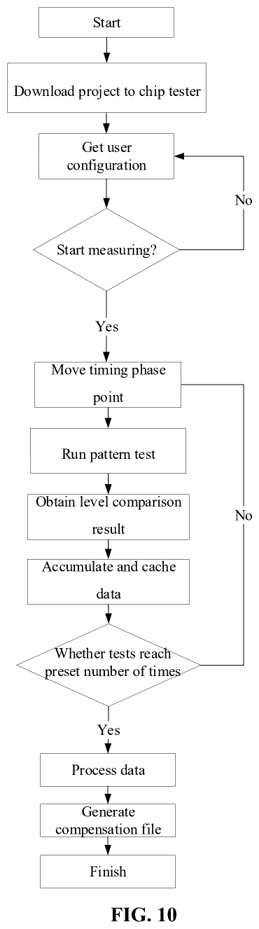

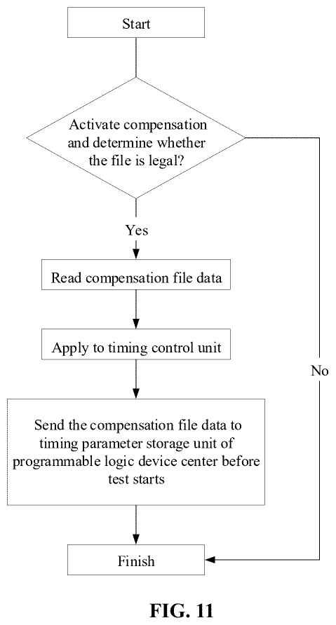

In an embodiment, as shown in FIG. 10, a method for measuring compensation for signal delay of a chip tester is provided, which can be applied to the system for measuring compensation for signal delay of the chip tester shown in FIG. 9. The method for measuring compensation includes the following steps.

The host computer 70 downloads a preset project file to the chip tester. The preset project file includes configuration information such as the content of the pattern for test, level parameters, timing parameters, and measurement mode designed according to the principle of the time domain reflection.

The master control measurement module 702 obtains the configuration information and starts measuring, sets the preset number of vector signal tests to be performed on the target channel according to the measurement mode in the preset project, moves the timing phase point, and sends the data related the pattern such as the content of the pattern for test, the level parameters, the timing parameters, etc. to the pattern control module 704.

The pattern control module 704 sends the pattern data of a current vector signal test to the pattern data storage module 802 of the programmable logic device center 80.

The output module 804 runs the pattern test and outputs the test vector signal to the target channel according to the pattern data in the pattern data storage module 802.

The receiving and comparing module 806 obtains reflected vector signal data returned from the target channel, and compares the level at the timing phase point in the reflected vector signal with the preset comparison level to obtain a level comparison result.

The comparison data reader-writer 808 records the level comparison result and sends the level comparison result to the data reading and parsing module 706. After reading the level comparison result, the data reading and parsing module 706 performs binary conversion on the level comparison result to obtain data to be processed, and the data accumulation and processing module 708 accumulates and caches the data to be processed.

After the number of vector signal tests performed on the target channel reaches the preset number, the data accumulation and processing module 708 processes the accumulated and cached data to obtain signal delay compensation data.

The file generation module 710 generates the delay compensation file according to the signal delay compensation data.

FIG. 11 is a flowchart showing a method for implementing timing compensation in an embodiment, which can be applied to the system for measuring compensation for signal delay of the chip tester shown in FIG. 9. The method includes the following steps.

In response to an instruction to activate compensation, it is determined whether a compensation file is legal. The compensation file may be the delay compensation file generated by the file generation module 710 in FIG. 9 according to the signal delay compensation data.

If the compensation file is legal, compensation file data is read.

The compensation file data is applied to the timing control unit 7041.

Before the test starts, the compensation file data is sent to the timing parameter storage unit 8021 of the programmable logic device center 80. The compensation file data is configured to compensate the timing parameters to achieve timing compensation and timing synchronization of signals.

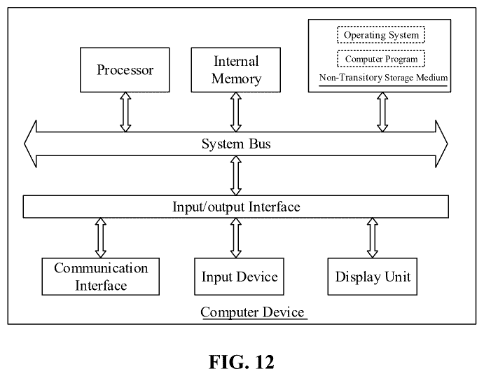

In another aspect, a computer device is provided according to an embodiment of the present disclosure. The computer device may be a terminal. A diagram illustrating an internal configuration of the computer device may be shown in FIG. 12. The computer device includes a processor, a memory, a communication interface, a display screen, and an input device which are connected via a system bus. The processor of the computer device is configured to provide computing and control capabilities. The memory of the computer device includes a non-transitory storage medium and an internal memory. The non-transitory storage medium stores an operating system and a computer program. The internal memory provides an environment for the operation of the operating system and the computer program in the non-transitory storage medium. The communication interface of the computer device is configured to communicate with external terminals in wired or wireless mode, which can be realized by WIFI, mobile cellular network, near field communication (NFC) or other technologies. The computer program, when executed by the processor, implements the above measurement methods. The display screen of the computer device may be an LCD or e-ink display. The input device of the computer device may be a touch layer covered on the display screen, or a key, trackball or trackpad set on the housing of the computer device, or an external keyboard, trackpad or mouse, etc.

It should be understood by a person of ordinary skill in the art that the configuration illustrated in FIG. 12 is only a block diagram of part of the configuration related to the solution of the present disclosure, and does not constitute a limitation on the computer device to which the solution of the present disclosure is applied. A specific computer device may include more or less components than those shown in FIG. 12, or may combine some components, or may have a different arrangement of components.

In an embodiment, a computer device is further provided, including a memory and a processor. The memory stores a computer program, and the processor, when executing the computer program, performs the steps of each method according to the foregoing embodiments.

In another aspect, a chip tester is provided according to an embodiment of the present disclosure. The chip tester includes a processor and a memory. The memory includes a non-transitory storage medium and an internal memory. The memory stores a computer program. The processor is configured to provide computing and control capabilities, and the processor, when executing the computer program, performs the steps in each method according to the foregoing embodiments. In some other implementations, the memory may alternatively be an external memory.

In another aspect, a computer-readable storage medium is provided according to an embodiment of the present disclosure, on which a computer program is stored. When the computer program is executed by a processor, the steps in each method according to the foregoing embodiments are performed.

A person of ordinary skill in the art may understand that implementation of all or part of the processes in the methods of the above embodiments may be completed by instructing the relevant hardware through a computer program. The computer program may be stored in a non-transitory computer-readable storage medium. When the computer program is executed, it may include the processes of the respective methods according to the foregoing embodiments. Any reference to memory, database or other medium used of the embodiments provided in the present disclosure may include at least one of a non-transitory or a transitory memory. The non-transitory memory may include a read-only memory (ROM), a magnetic tape, a floppy disk, a flash memory, an optical memory, etc. The transitory memory may include a random-access memory (RAM) or an external cache, etc. As an illustration rather than a limitation, the random-access memory may be in various forms, such as a static random-access memory (SRAM) or a dynamic random-access memory (DRAM), etc. The database involved in the embodiments provided by the present disclosure may include at least one of a relational database and a non-relational database. The non-relational database may include, but is not limited to, a blockchain-based distributed database, etc. The processor involved in the embodiments provided by the present disclosure may be, but is not limited to, a general purpose processor, a central processing unit, a graphics processing unit, a digital signal processor, a programmable logic device, a data processing logic device based on quantum computation, and the like.

The technical features in the above embodiments may be combined arbitrarily. For concise description, not all possible combinations of the technical features in the above embodiments are described. However, provided that they do not conflict with each other, all combinations of the technical features are to be considered to be within the scope of protection of the present disclosure.

The above-mentioned embodiments only describe several implementations of the present disclosure, and their description is specific and detailed, but should not be understood as a limitation on the protection scope of the present disclosure. It should be noted that, for a person of ordinary skill in the art, various variations and improvements can be further made without departing from the conception of the present disclosure, and these all fall within the protection scope of the present disclosure. Therefore, the protection scope of the present disclosure should be subject to the appended claims.

1. A method for measuring signal delay of a chip tester, comprising:
performing a vector signal test on a target channel, the vector signal test utilizing a test vector signal, with a timing phase point, generated by the chip tester;
wherein performing the vector signal test on the target channel comprises:
sending the test vector signal to the target channel;
obtaining a reflected vector signal of the test vector signal; and
comparing a level at the timing phase point in the reflected vector signal with a preset comparison level, and recording a level comparison result;
moving a position of the timing phase point in the test vector signal upon completion of the vector signal test, and re-performing a vector signal test on the target channel;
repeating processes of moving the position of the timing phase point and re-performing the vector signal test on the target channel until a number of vector signal tests reaches a preset standard; and
when the number of the vector signal tests reaches the preset standard, obtaining level comparison results of the number, and performing a delay calculation based on the level comparison results of the number to obtain signal delay time.

2. The method according to claim 1, wherein after recording the level comparison result, the method further comprises:
performing a binary processing on the level comparison result to obtain data to be processed; and
performing data accumulation on the data to be processed, a result of the data accumulation being applied to the delay calculation which is performed after the number of the vector signal tests reaches the preset standard to obtain the signal delay time.

3. The method according to claim 2, wherein performing the binary processing on the level comparison result to obtain the data to be processed comprises:
recording the level comparison result as a first value in a case that the level of the timing phase point is lower than the preset comparison level, and recording the level comparison result as a second value different from the first value in a case that the level of the timing phase point is higher than the preset comparison level.

4. The method according to claim 1, wherein before performing the vector signal test on the target channel, the method further comprises:
determining a measurement mode, wherein each measurement mode has a corresponding number of vector signal tests; and
determining the preset standard for the number of the vector signal tests according to the measurement mode.

5. The method according to claim 4, wherein the measurement mode comprises one or more selected from a group consisting of a performance mode, a balance mode, and a fast mode;
a number of tests for the performance mode, a number of tests for the balance mode, and a number of tests for the fast mode decrease sequentially;
a test accuracy of the performance mode, a test accuracy of the balance mode, and a test accuracy of the fast mode decrease sequentially; and
a moving interval of the timing phase point for the performance mode, a moving interval of the timing phase point for the balance mode, and a moving interval of the timing phase point for the fast mode increase sequentially.

6. The method according to claim 1, wherein moving the position of the timing phase point comprises:
obtaining a current test order;
calculating a displacement distance according to the current test order and a preset point moving step; and
moving the timing phase point by the displacement distance to a target position.

7. The method according to claim 1, wherein after obtaining the signal delay time, the method further comprises:
generating time compensation data according to the signal delay time, the time compensation data being utilized by the chip tester to implement signal timing compensation.

8. The method according to claim 1, wherein after obtaining the signal delay time, the method further comprises:
changing a length of the target channel;
performing signal delay measurement on the target channel with the changed length to obtain a displacement signal delay time; and
generating displacement difference time compensation data according to a difference between the signal delay time and the displacement signal delay time.

9. The method according to claim 1, wherein moving the position of the timing phase point comprises:
setting a comparison point step, the comparison point step being a fixed length of time; and
moving the timing phase point by a distance equal to the comparison point step within a cycle.

10. The method according to claim 9, wherein performing the delay calculation based on the level comparison results of the number to obtain the signal delay time comprises:
finding, from the level comparison results of the number, a timing phase point at which the level of the timing phase point is higher than the preset comparison level to obtain a target timing phase point;
obtaining a basic time according to a serial number of a cycle in which the target timing phase point is located;
calculating an additional time according to an initial position of the target timing phase point, the number, and a magnitude of the comparison point step; and
adding the basic time and the additional time to obtain the signal delay time.

11. The method according to claim 1, wherein the test vector signal is pre-set with the timing phase point in each cycle, and positions of the timing phase points in respective cycles are the same.

12. The method according to claim 1, wherein sending the test vector signal to the target channel comprises:
setting an end of the target channel to be an open circuit state, and sending the test vector signal with the timing phase point to the target channel; wherein the target channel is a line channel through which a signal is sent to a location for placing a chip under test.

13. (canceled)

14. An apparatus for measuring signal delay of a chip tester, comprising a memory and a processor, the memory storing a computer program thereon, wherein the processor, when executing the computer program, performs following steps:
performing a vector signal test on a target channel, the vector signal test utilizing a test vector signal, with a timing phase point, generated by the chip tester;
wherein performing the vector signal test on the target channel comprises:
sending the test vector signal to the target channel;
obtaining a reflected vector signal of the test vector signal; and
comparing a level at the timing phase point in the reflected vector signal with a preset comparison level, and recording a level comparison result;
moving a position of the timing phase point in the test vector signal upon completion of the vector signal test, and re-performing a vector signal test on the target channel;
repeating processes of moving the position of the timing phase point and re-performing the vector signal test on the target channel until a number of vector signal tests reaches a preset standard; and
when the number of the vector signal tests reaches the preset standard, obtaining level comparison results of the number, and performing a delay calculation based on the level comparison results of the number to obtain signal delay time.

15. A chip tester, comprising a memory and a processor, the memory storing a computer program thereon, wherein the processor, when executing the computer program, performs following steps:
performing a vector signal test on a target channel, the vector signal test utilizing a test vector signal, with a timing phase point, generated by the chip tester;
wherein performing the vector signal test on the target channel comprises:
sending the test vector signal to the target channel;
obtaining a reflected vector signal of the test vector signal; and
comparing a level at the timing phase point in the reflected vector signal with a preset comparison level, and recording a level comparison result;
moving a position of the timing phase point in the test vector signal upon completion of the vector signal test, and re-performing a vector signal test on the target channel;
repeating processes of moving the position of the timing phase point and re-performing the vector signal test on the target channel until a number of vector signal tests reaches a preset standard; and
when the number of the vector signal tests reaches the preset standard, obtaining level comparison results of the number, and performing a delay calculation based on the level comparison results of the number to obtain signal delay time.
